(19) United States
(12) Patent Application Publication
(10) Pub. No.: US 2011/0241026 A1
(43) Pub. Date: Oct. 6, 2011

(54) LIGHT-EMITTING DIODE CHIP AND PACKAGE STRUCTURE THEREOF

(75) Inventors: HUNG-NAN CHEN, Kaohsiung City (TW); Wen-Hao Cheng, Taipei City (TW)

(73) Assignee: Orbit Semicon LTD., Kaohsiung City (TW)

(21) Appl. No.: 13/069,232

(22) Filed: Mar. 22, 2011

(30) Foreign Application Priority Data
Mar. 30, 2010 (TW) 099109543

(51) Int. Cl. H01L 27/15; H01L 33/40

(52) U.S. Cl. 257/88; 257/99; 257/E27.12; 257/E33.063

(57) ABSTRACT

A light-emitting diode chip includes a first electrode and a metal composite layer. The metal composite layer is disposed on the first electrode and has a nickel layer. Since the metal composite layer is disposed on the first electrode, the yield of the wedge bonding can be increased, and the chip damage can be avoided.

### CROSS REFERENCE TO RELATED APPLICATIONS

This Non-provisional application claims priority under 35 U.S.C. §119(a) on Patent Application No(s). 099109543 filed in Taiwan, Republic of China on Mar. 30, 2010, the entire contents of which are hereby incorporated by reference.

### BACKGROUND OF THE INVENTION

1. Field of Invention

This invention related to a light-emitting diode (LED) chip and a package structure thereof.

2. Related Art

Wire bonding is one of the major electrical connection techniques for an electronic package, and it can connect the chip to the package substrate, circuit board or lead frame by metal wires, thereby achieving the electrical signals communications and power distributions. Because the wire bonding is easy and convenient to be applied in new processes, the related technique and machines are well developed, and the automation and wire bonding speed have been made significant progresses recently, the wire bonding technique is still the major technique for the semiconductor assembly market.

The wire boning process of an LED chip will be taken for an example and the process will be explained hereinbelow. FIG. 1 and FIG. 2 are schematic diagrams showing a conventional wire bonding process. As shown in FIG. 1, in the conventional wire bonding process, the front end of the wire 12 exposed at the nozzle 11 is melt to form a ball 13. The nozzle is also called as capillary. Subsequently, as shown in FIG. 2, after the ball 13 has been formed, the nozzle 11 presses the ball 13 to an electrode 141 of the LED chip and apply heat and ultrasonic energy to form an alloy interconnection. This step is called “ball bond”, and also called “first bond” because it is the bonding at the beginning To bond the ball 13 to the electrode 141, the front end of the nozzle 11 presses the ball 13 on the electrode 141 and the ultrasonic wave is applied. Using the heat of the process, the ball 13 and the electrode 141 are connected to each other, and complete the “first bond”. After that, the nozzle 11 moves along a predetermined pathway to a bonding pad 15 of the substrate with continuously releasing the wire 12 so as to perform the “second bond”, which is also called “wedge bond”. Finally, the nozzle 11 moves upward and snaps the wire 12.

Regarding to the variety demands of the LED product, there are more and more products needing wire bonding process for connecting a plurality of LED chips 14 in series or in parallel. In order to reduce the cost and substrate area required, a chip to chip direct wire bonding interconnection is needed. However, during the position of the wedge bond or “second bond” is on the electrode 141 of the LED chip 14, if the pressing force of the nozzle 11 is too small, the eutectic bonding may not be properly formed. This can decrease the reliability of the products. Otherwise, if the pressing force of the nozzle is too large, the LED chip 14 may be easily broken, thereby decreasing the production yield. Especially for the LED chip 14 made of GaAs thin film, because the mechanical strength of the GaAs thin film is weaker, it is easily broken during the wedge bonding process.

Therefore, it is an important subject to provide an LED chip and a package structure thereof to solve existing bottlenecks encountered.

### SUMMARY OF THE INVENTION

In view of the foregoing subject, an objective of the present invention is to provide an LED chip and a package structure thereof for improving the yield of wedge bond and avoiding the LED chip from damage.

To achieve the above objective, the present invention discloses an LED chip includes a first electrode and a metal composite layer. The metal composite layer is disposed on the first electrode and has a nickel layer.

To achieve the above objective, the present invention discloses an LED package structure includes a substrate, a wire and an LED chip. The LED chip is disposed on the substrate. The LED chip has a first electrode and a metal composite layer. The metal composite layer is disposed on the first electrode and has a nickel layer. One end of the wire is connected with the metal composite layer.

In one embodiment of the present invention, the thickness of the nickel layer is between 1.0 μm and 15 μm.

In one embodiment of the present invention, the metal composite layer further includes a gold layer and/or a silver layer and/or a palladium layer.

In one embodiment of the present invention, the thickness of the gold layer is between 0.01 μm and 1.5 μm.

In one embodiment of the present invention, the thickness of the silver layer is between 1 μm and 10 μm.

In one embodiment of the present invention, the thickness of the palladium layer is between 0.03 μm and 0.3 μm.

In one embodiment of the present invention, the LED chip further includes a second electrode, which is disposed corresponding to the first electrode.

In one embodiment of the present invention, the substrate is a ceramic circuit board, a glass circuit board, a printed circuit board, a metal core printed circuit board, or a lead frame.

In one embodiment of the present invention, the LED chip further includes an insulating substrate disposed on the substrate.

In one embodiment of the present invention, the other end of the wire is electrically connected to another LED chip.

In one embodiment of the present invention, the LED chips are electrically connected in series or in parallel.

As mentioned above, the LED chip and LED package structure according to the invention have the metal composite layer disposed on the first electrode so as to provide the sufficient mechanical strength support for the first electrode. Thus, the wedge bonding pressure of the nozzle can be dispersed, and the epitaxy layer under the first electrode can be protected, which avoids the epitaxy layer from being damaged during the wedge bonding process. Thus, the process yield of the wedge bonding process can be improved. Moreover, disposing the metal composite layer on the first electrode can reduce the thickness of the gold layer and lower the material cost.

### BRIEF DESCRIPTION OF THE DRAWINGS

The invention will become more fully understood from the detailed description and accompanying drawings, which are given for illustration only, and thus are not limitative of the present invention, and wherein:

FIG. 1 is a diagram showing a nozzle of the conventional wire bonding process;

FIG. 2 is a diagram showing the conventional wire bonding process;

FIG. 3 is a diagram showing the LED chip according to the preferred embodiment of the invention;

FIG. 4 is a diagram showing the other LED chip according to the preferred embodiment of the invention; and

FIG. 5 is a diagram showing the LED package structure according to the preferred embodiment of the invention.

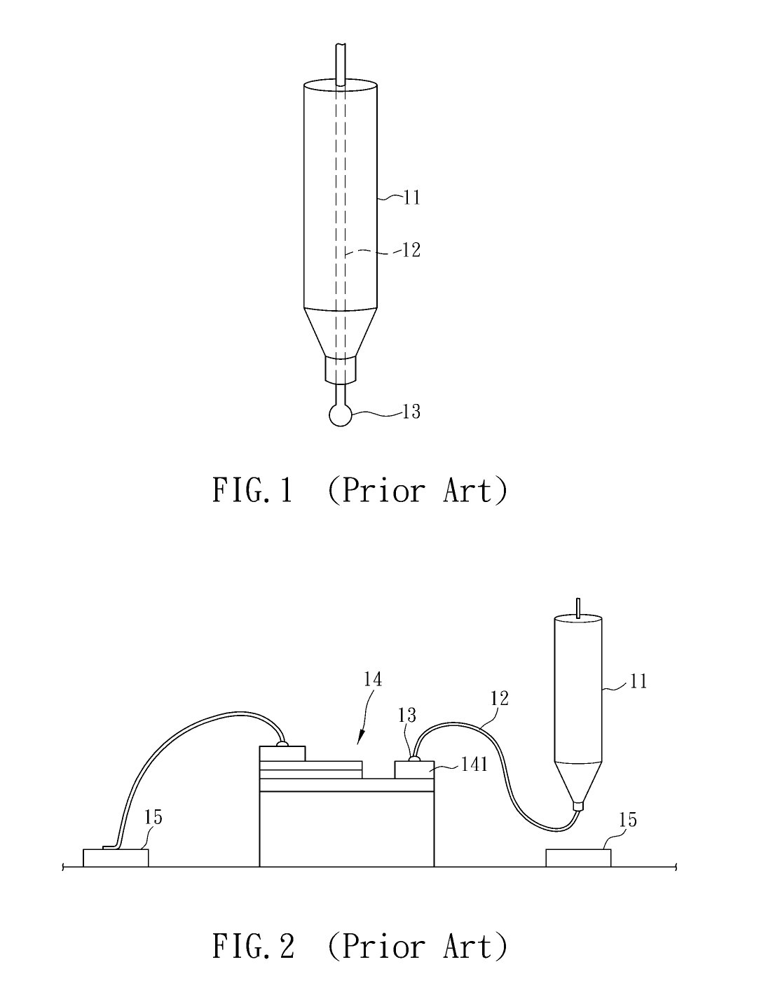

### DETAILED DESCRIPTION OF THE INVENTION

The present invention will be apparent from the following detailed description, which proceeds with reference to the accompanying drawings, wherein the same references relate to the same elements.

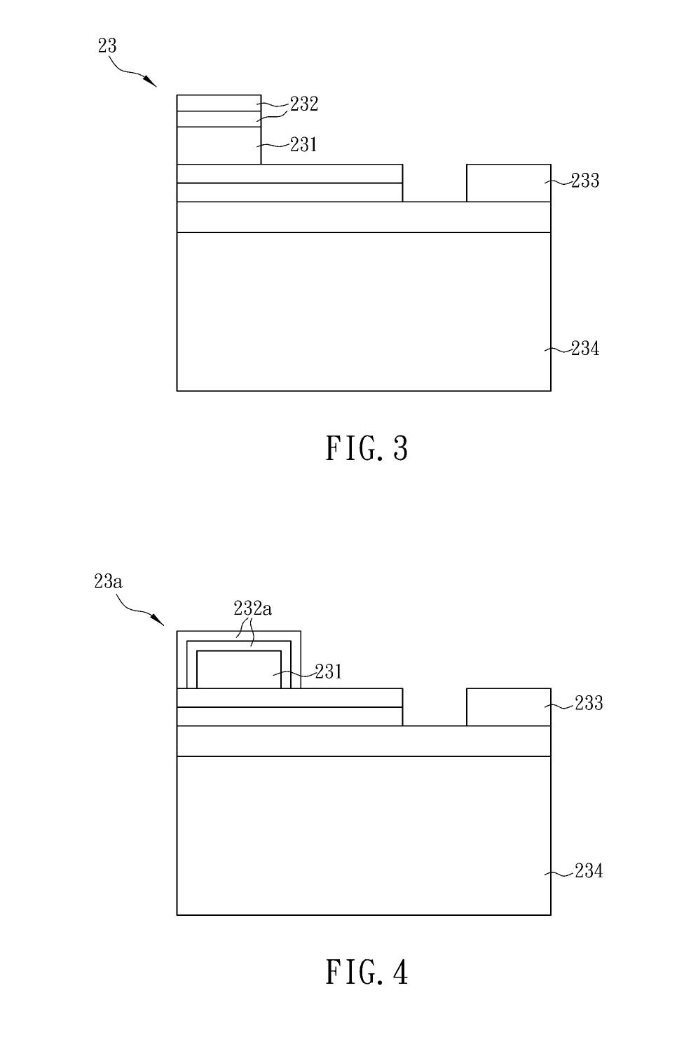

Referring to FIG. 3, it is a schematic illustration showing a light-emitting diode (LED) chip according to a preferred embodiment of the invention. The LED chip (or die) 23 can emit red, blue, UV, white, or other colors of light. In this embodiment, the LED chip 23 can emit blue light for example. The LED chip 23 includes a first electrode 231 and a metal composite (or metal finish) layer 232. In this case, the LED chip 23 may be a bare chip or a packaged LED chip.

The first electrode 231 may include a palladium layer and a gold layer combination (Pd/Au) or a chromium layer, a platinum layer and a gold layer combination (Cr/Pt/Au). In this embodiment, the total thickness of the first electrode 231 is about 1.2 μm, and the thickness of the gold layer is about 1 μm.

The metal composite layer 232 is disposed on the first electrode 231 by electroless chemical deposition or by electrical plating. FIG. 4 is a diagram showing the other LED chip according to the preferred embodiment of the invention. Referring to FIG. 3 and FIG. 4, the profiles of the metal composite layer 232 disposed on the first electrode 231 are different depends on the processes. If the deposition and photo lithography processes of the metal composite layer 232 are integrated with those processes of the first electrode 231, the metal composite layer 232 may be similar to that shown in FIG. 3 and directly stack on the top surface of the first electrode 231. If the chemical deposition (electroless plating) is performed to form the metal composite layer 232a after the formation of the first electrode layer 231, the metal composite layer 232a may be similar to that shown in FIG. 4, and cover the outer surface as well as the sidewalls of the first electrode 231.

The metal composite layer 232 includes at least a nickel layer. The mechanical strength of the nickel metal can provide the supporting strength for the first electrode layer 231 to resist the bonding pressure from wedge bonding. Of course, the metal composition layer 232 may have two or more metal layers consisting of different materials, and this is not limited in this invention. When the metal composite layer 232 has two metal layers, one of them is a nickel layer, and the other one may be a gold layer, a silver layer or a palladium layer. The sequence of the metal layers from inside (closer to the first electrode 231) to outside is Ni/Au, Ni/Ag, or Ni/Pd. When the metal composite layer 232 has three metal layers (not shown in figures), the sequence of the metal layers from inside (closer to the first electrode 231) to outside is Ni/Ag/Au or Ni/Pd/Au. In this case, the thickness of the nickel layer is from 1.0 μm to 15 μm, the thickness of the gold layer is from 0.01 μm to 1.5 μm, the thickness of the silver layer is from 1.0 μm to 15 μm, and the thickness of the palladium layer is from 0.03 μm to 0.3 μm. In more detailed, if the metal composite layer 232 has two metal layers, the thickness of the gold layer is preferably between 0.15 μm and 1.5 μm. Otherwise, if the metal composite layer 232 has three metal layers, the thickness of the gold layer is preferably between 0.01 μm and 0.5 μm. To be noted, when the nickel layer is formed by electroless chemical deposition, the hardness of the nickel layer would be lower. For enhancing the hardness of the nickel layer, during the deposition process, 3-5% phosphor may be added in the nickel layer.

Referring to FIG. 3 and FIG. 4, the LED chip 23 of the embodiment further includes a second electrode 233, which is disposed corresponding to the first electrode 231. In this case, the second electrode 233 and the first electrode 231 are disposed on the same side of the LED chip 23. Besides, it is possible to dispose another metal composite layer on the second electrode 233. However, this embodiment does not configure the additional metal composite layer on the second layer 233.

The LED chip 23 of the embodiment may further include an insulating substrate 234, which is disposed on the substrate 21. The insulating substrate 234 can be an insulator at the bottom of the LED chip 23.

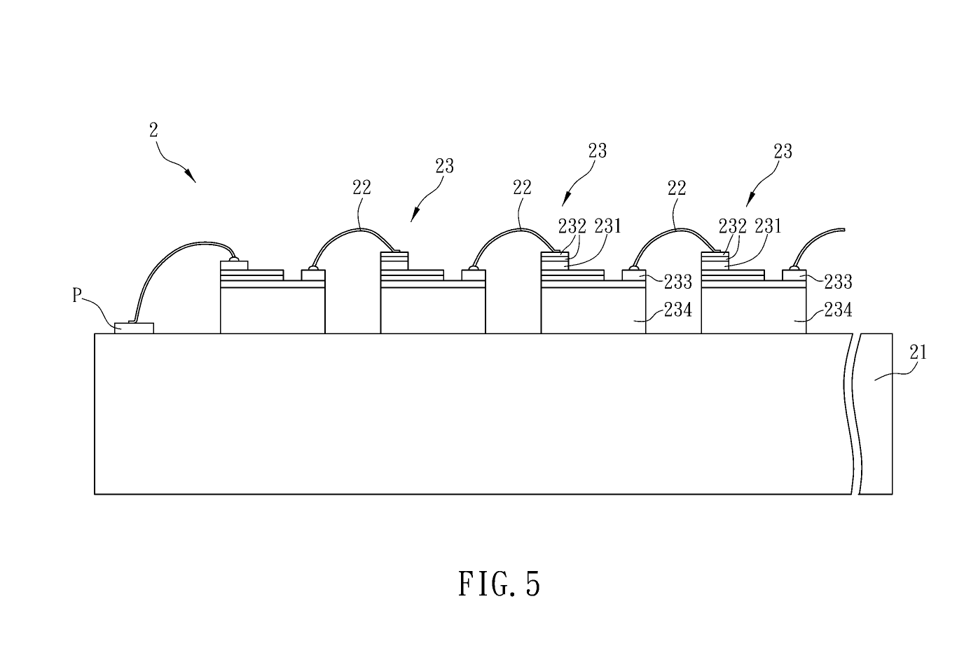

FIG. 5 is a diagram showing the LED package structure according to the preferred embodiment of the invention. Referring to FIG. 5, the LED package structure 2 includes a substrate 21, a wire 22 and at least one LED chip 23. In this case, the LED package structure 2 has a plurality of wires 22 and a plurality of LED chips 23 (at least two LED chips 23). The LED chips 23 are disposed on the substrate 21 and electrically connect to each other by those wires 22. The LED chips 23 can be electrically connected in series or in parallel. As shown in FIG. 5, the LED chips 23 are wire bonded in series.

The substrate 21 can be a ceramic circuit board, a glass circuit board, a printed circuit board, a metal core printed circuit board, or a lead frame. The substrate 21 has a circuit layer on the upper surface thereof, and the first and last LED chips 23 in the series can be wire bonded to the bonding pads P of the circuit layer on the substrate 21.

In this case, the material of the wire 22 is, for example but not limited to, gold. The material of the wire 22 can also be copper, aluminum, silver or other materials. Depending on the package of the semiconductor, the type or the radius of the wire or the parameter of the bonder machine is different. The strength and the loop of the wire 22 depends on the percentage of the metal (ex: Ag, Cu, Fe, Mg, Pd) added in the wire 22.

Among the LED chips 23, at least one LED chip 23 includes a first electrode 231 and a metal composite layer 232. In this case, the metal composite layer 232 is disposed on the first electrode 231 and has a nickel layer. The structure of the LED chip 23 is described as previous, and has the same technical feature, so the detailed descriptions thereof will not be described again.

When connecting the second electrode 233 of one LED chip 23 to the first electrode 231 of another LED chip 23 by wire bonding process, the bonding process of the wire 22 (with ball formed) and the second electrode 233 is called a first bond. In addition, the bonding process of the wire 22 and the first electrode 233 is called a wedge bond or a second bond. Because the metal composite layer 232 disposed on the first electrode 231 can provide the mechanical strength support for the first electrode 231, the wedge bonding pressure of the nozzle could be dispersed or eased, and the epitaxy layer under the first electrode 231 could be protected. For example, the GaAs epitaxy layer of the blue LED chip is very weak. Such that, the process yield of the wedge bonding process could be improved. Moreover, the product reliability of the LED chip 23 is also increased.

In summary, the LED chip and LED package structure according to the invention have the metal composite layer disposed on the first electrode so as to provide the sufficient mechanical strength support for the first electrode. Thus, the wedge bonding pressure of the nozzle can be dispersed, and the epitaxy layer under the first electrode can be protected, which avoids the epitaxy layer from been broken during the wedge bonding process. Thus, the process yield of the wedge bonding process can be improved. Moreover, disposing the metal composite layer on the first electrode can reduce the thickness of the gold layer, for example, from 1 μm to 0.1 μm and lower the material cost.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A light-emitting diode (LED) chip, comprising:
a first electrode; and
a metal composite layer disposed on the first electrode and comprising a nickel layer.

2. The LED chip according to claim 1, wherein the thickness of the nickel layer is between 1.0 μm and 15 μm.

3. The LED chip according to claim 1, wherein the metal composite layer further comprises a gold layer and/or a silver layer and/or a palladium layer.

4. The LED chip according to claim 3, wherein the thickness of the gold layer is between 0.01 μm and 1.5 μm.

5. The LED chip according to claim 3, wherein the thickness of the silver layer is between 1 μm and 10 μm.

6. The LED chip according to claim 3, wherein the thickness of the palladium layer is between 0.03 μm and 0.3 μm.

7. The LED chip according to claim 1, further comprising:
a second electrode disposed corresponding to the first electrode.

8. A light-emitting diode (LED) package structure, comprising:
a substrate;
a wire; and
at least an LED chip disposed on the substrate and comprising a first electrode and a metal composite layer, wherein the metal composite layer is disposed on the first electrode and comprises a nickel layer, and one end of the wire is connected with the metal composite layer.

9. The package structure according to claim 8, wherein the substrate is a ceramic circuit board, a glass circuit board, a printed circuit board, a metal core printed circuit board, or a lead frame.

10. The package structure according to claim 8, wherein the LED chip further comprises an insulating substrate disposed on the substrate.

11. The package structure according to claim 8, wherein the other end of the wire is electrically connected to another LED chip.

12. The package structure according to claim 8, wherein the LED chips are electrically connected in series or in parallel.

13. The package structure according to claim 8, wherein the thickness of the nickel layer is between 1.0 μm and 15 μm.

14. The package structure according to claim 8, wherein the metal composite layer further comprises a gold layer and/or a silver layer and/or a palladium layer.

15. The package structure according to claim 8, wherein the thickness of the gold layer is between 0.01 μm and 1.5 μm.

16. The package structure according to claim 14, wherein the thickness of the silver layer is between 1 μm and 10 μm.

17. The package structure according to claim 14, wherein the thickness of the palladium layer is between 0.03 μm and 0.3 μm.
